(19) United States
(12) Patent Application Publication
(10) Pub. No.: US 2025/0175166 A1
(43) Pub. Date: May 29, 2025

(54) AN ELECTRICAL PULSE GENERATING ARRANGEMENT

(71) Applicant: ScandiNova Systems AB, Uppsala (SE)

(72) Inventors: Klas Elmquist, Uppsala (SE); Per Nilsson, Uppsala (SE)

(73) Assignee: ScandiNova Systems AB, Uppsala (SE)

(21) Appl. No.: 18/715,706

(22) PCT Filed: Nov. 17, 2022
(86) PCT No.: PCT/EP2022/082194

§ 371 Date: Jun. 1, 2024

(30) Foreign Application Priority Data
Dec. 6, 2021 (EP) 21212531.4

(51) Int. Cl. H03K 3/57

(52) U.S. Cl. CPC H03K 3/57

(57) ABSTRACT

An electrical pulse generating arrangement is disclosed, which is connected or connectable to a load. The electrical pulse generating arrangement comprises an electrical pulse generating module, which comprises a first electrical energy storage module and a power supply configured to selectively charge the first electrical energy storage module. The electrical pulse generating module is configured to generate one or more electrical pulses by charging and discharging of the first electrical energy storage module, wherein when the first electrical energy storage module is discharged, an electrical pulse is created to be conveyed to the load. The electrical pulse generating arrangement comprises an electrical pulse shape adjustment circuit connected or connectable in series with the load. The electrical pulse shape adjustment circuit comprises at least a first resistor, an inductor and a second electrical energy storage module.

### TECHNICAL FIELD

The present invention generally relates to the field of electrical equipment. Specifically, the present invention relates to an electrical pulse generating arrangement.

### BACKGROUND

Electrical pulses may be employed in a variety of applications, such as, for example, radar systems, particle accelerators, sterilization equipment, high-energy lasers, microwave systems, or medical devices. In such and other applications it may be desired or required to deliver one or more electrical pulses to a load.

An electrical energy storage unit or module such as a capacitor may be used to store electrical energy, which when discharged generates an electrical pulse that can be delivered to the load, or to a pulse transformer. The capacitor may be repeatedly charged by a power supply unit or arrangement connected to a power source. The capacitor may be repeatedly or cyclically charged and discharged in order to generate a plurality of successive electrical pulses. Arrangements, systems or circuits which are employed for generating electrical pulses may be referred to as power modulators. Power modulators may employ a pulse transformer in order to obtain the required or desired voltage of the electrical pulses.

### SUMMARY

An electrical pulse generating module in a power modulator may employ a power supply and an electrical energy storage module that can be charged or discharged. The electrical energy storage module may for example comprise a capacitor or several capacitors (e.g., a capacitor bank). Electrical pulses may be generated by repeatedly or cyclically charging and discharging the electrical energy storage module, wherein when the electrical energy storage module is discharged, an electrical pulse is generated which may be conveyed to, and received by, a transformer (e.g., a voltage step-up transformer) connected to a load. Possibly, the electrical pulse may be delivered or conveyed directly to the load. The electrical energy storage module may be partially or completely charged and discharged. After the electrical energy storage module has been discharged to generate an electrical pulse, the electrical energy storage module should be charged again in preparation for the next electrical pulse.

In order to carry out the charging and discharging of the electrical energy storage module, a switch or switching device may be included in the electrical pulse generating module, which may selectively connect or disconnect a power supply with the electrical energy storage module. The switch or switching device of an electrical pulse generating module that is based on discharge of an electrical energy storage module such as a capacitor may be referred to as a pulse switch or pulse switching device.

While in the following the electrical energy storage module may be referred to as a capacitor, it is to be understood that more than one capacitor and/or another or other types of electrical energy storage modules than capacitors may possibly be used, e.g., inductive electrical energy storage modules. Thus, even if the electrical energy storage module in the following may be referred to as a capacitor, the disclosure herein is applicable in the same way or similarly for other types of electrical energy storage modules than capacitors.

In power modulators based on discharge of an electrical energy storage module such as a capacitor, the ‘droop’ in voltage of the capacitor during discharge of the capacitor may cause droop in voltage of the electrical pulse generated by the discharge of the capacitor. The shape of the electrical pulse generated by the discharge of the capacitor may thereby not be ‘flat’ or substantially ‘flat’—i.e. have a constant amplitude or substantially constant amplitude from the trailing edge of the electrical pulse to the leading edge of the electrical pulse—but may have an amplitude that is decreasing (e.g., monotonously decreasing) from the trailing edge of the electrical pulse to the leading edge of the electrical pulse. In many applications such a voltage droop is acceptable, but in some applications, such as driving a microwave amplifier by way of the generated electrical pulses, such a voltage droop may not be acceptable.

In order to compensate for such voltage droop and for trying to attain a ‘flat’ electrical pulse, a parallel R-L circuit may be used. The parallel R-L circuit may comprise a resistor and an inductor which are interconnected, and the parallel R-L circuit may be connected between the capacitor and the load. As the pulse switch is switched in order to begin the electrical pulse (e.g., when the pulse switch selectively disconnects the power supply from the electrical energy storage module), the entire (or substantially the entire) current of the electrical pulse passes through the resistor in the parallel R-L circuit at the beginning of the electrical pulse. Thus, the resistor in the parallel R-L circuit is ‘active’ from the beginning of the electrical pulse, and causes a voltage drop across the parallel R-L circuit. The resistance of the resistor in the parallel R-L circuit is selected in order to obtain a voltage drop across the parallel R-L circuit for compensating for the droop in voltage of the electrical pulse by the discharge of the capacitor. The inductor in the parallel R-L circuit carries no current at the beginning of the electrical pulse. During the discharge of the capacitor—and hence during the duration of the electrical pulse—current builds up in inductor in the parallel R-L circuit. As a consequence, the voltage drop across the resistor in the parallel R-L circuit decreases. With an appropriate selection of the inductance of the inductor in the parallel R-L circuit, this may compensate for the decreasing voltage of the capacitor as a result of its discharge so as to achieve a ‘flat’ or substantially ‘flat’ electrical pulse.

However, while such a parallel R-L circuit may compensate for voltage droop and achieve a ‘flat’ or substantially ‘flat’ electrical pulse, use of such a parallel R-L circuit may increase the rise time of the electrical pulse to an extent that may not be acceptable in some applications. This is at least in part due to that the resistor in the parallel R-L circuit is ‘active’ from the beginning of the electrical pulse, and causes a voltage drop across the parallel R-L circuit from the beginning of the electrical pulse. If the rise time of the electrical pulse increases, the duration of the electrical pulse (or ‘width’ of the electrical pulse) may decrease, which may be undesired in some applications.

In view of the above, a concern of the present invention is to provide an electrical pulse generating module that is based on discharge of an electrical energy storage module such as a capacitor, which electrical pulse generating module is capable of generating ‘flat’ or substantially ‘flat’ electrical pulses while having a relatively fast rise time.

To address at least one of this concern and other concerns, an electrical pulse generating arrangement in accordance with the independent claim is provided. Preferred embodiments are defined by the dependent claims.

According to a first aspect an electrical pulse generating arrangement is provided. The electrical pulse generating arrangement is connected or connectable to a load. The electrical pulse generating arrangement comprises an electrical pulse generating module. The electrical pulse generating module comprises a first electrical energy storage module and a power supply configured to selectively charge the first electrical energy storage module. The electrical pulse generating module is configured to generate one or more electrical pulses by charging and discharging of the first electrical energy storage module, wherein when the first electrical energy storage module is discharged, an electrical pulse is created to be conveyed to the load. The electrical pulse generating arrangement comprises an electrical pulse shape adjustment circuit connected or connectable with the load, e.g., connected or connectable in series with the load. The electrical pulse shape adjustment circuit comprises at least a first resistor, an inductor and a second electrical energy storage module. The first resistor, the inductor and the second electrical energy storage module are interconnected.

The electrical pulse shape adjustment circuit may be connected between the switch unit and the load. Each or any of the first electrical energy storage module and the second electrical energy storage module may for example comprise one or more capacitors.

By the providing of the electrical pulse shape adjustment circuit in the electrical pulse generating arrangement, any droop in voltage of the electrical pulse(s) generated by the discharge of the first electrical energy storage module due to the ‘droop’ in voltage of the first electrical energy storage module during discharge thereof may be compensated for, in order to attain electrical pulse(s) having a ‘flat’ or substantially ‘flat’ shape (at least during part of the duration of the electrical pulse(s)), or at least electrical pulse(s) coming closer to having such a ‘flat’ shape. This may be achieved at least in part by means of the first resistor and the inductor of the electrical pulse shape adjustment circuit, similarly to using a parallel R-L circuit for example such as described in the foregoing.

The second electrical energy storage module of the electrical pulse shape adjustment circuit may facilitate or allow for ensuring that the first resistor of the electrical pulse shape adjustment circuit is not ‘active’ from the beginning of the electrical pulse, due to the second electrical energy storage module of the electrical pulse shape adjustment circuit being charged at the beginning of the electrical pulse. Specifically, by means of the providing of the second electrical energy storage module of the electrical pulse shape adjustment circuit, compensation for any droop in voltage of the electrical pulse(s) generated by the discharge of the first electrical energy storage module may take place not from the very beginning of the electrical pulse(s), but only after a selected part of the duration of the electrical pulse(s) has elapsed. After this, compensation for any droop in voltage of the electrical pulse(s) may take place during the remainder of the electrical pulse(s). For example, by means of the providing of the second electrical energy storage module in the electrical pulse shape adjustment circuit, compensation for any droop in voltage of the electrical pulse(s) generated by the discharge of the first electrical energy storage module could take place during, e.g., the second half of the duration of the electrical pulse(s), but not during, e.g., the first half of the duration of the electrical pulse(s).

The second electrical energy storage module of the electrical pulse shape adjustment circuit may start being charged upon the pulse switch being switched in order to begin the electrical pulse (e.g., when the pulse switch selectively disconnects the power supply from the electrical energy storage module). Once the second electrical energy storage module of the electrical pulse shape adjustment circuit has been charged to attain a certain voltage, the first resistor of the electrical pulse shape adjustment circuit may become ‘active’. The certain voltage of the second electrical energy storage module at which the first resistor becomes ‘active” may be based on the characteristics of the components of electrical pulse shape adjustment circuit (e.g., the resistance of the first resistor, the inductance of the inductor and/or the capacity of the second electrical energy storage module to store electrical energy (e.g., capacitance)). Of the characteristics of the components of electrical pulse shape adjustment circuit, the certain voltage of the second electrical energy storage module at which the first resistor becomes ‘active” may depend most strongly on the resistance of the first resistor and the capacity of the second electrical energy storage module to store electrical energy (e.g., capacitance).

Generally, by means of the providing of the second electrical energy storage module in the electrical pulse shape adjustment circuit, there may be no compensation for any droop in voltage of the electrical pulse(s) generated by the discharge of the first electrical energy storage module during a first part of the duration of the electrical pulse(s), while during the remainder of the duration of the electrical pulse(s) there may be compensation for any droop in voltage of the electrical pulse(s) generated by the discharge of the first electrical energy storage module.

By configuring and/or selecting the second electrical energy storage module in the electrical pulse shape adjustment circuit appropriately, the electrical pulse shape adjustment circuit can be configured such that the compensation for any droop in voltage of the electrical pulse(s) becomes active at a selected point in time during the duration of the electrical pulse. Prior to that point in time during the duration of the electrical pulse, there may be no compensation for any droop in voltage of the electrical pulse(s). As mentioned, the second electrical energy storage module may for example comprise or more capacitors. A configuration of the electrical pulse shape adjustment circuit to make the compensation for any droop in voltage of the electrical pulse(s) become active at a selected point in time during the duration of the electrical pulse may for example be carried out by providing a second electrical energy storage module that has a selected capacitance or a capacitance within a selected capacitance range.

By not having any compensation for any droop in voltage of the electrical pulse(s) generated by the discharge of the first electrical energy storage module at the beginning of the electrical pulse(s), the rise time of the electrical pulse(s) may be faster as compared to if the first resistor of the electrical pulse shape adjustment circuit would be ‘active’ from the beginning of the electrical pulse(s). The use of the electrical pulse shape adjustment circuit in the electrical pulse generating arrangement may entail no, or substantially no increase in rise time of the electrical pulse(s), as compared to if a parallel R-L circuit such as described in the foregoing would be employed in lieu of the above-mentioned electrical pulse shape adjustment circuit.

The second electrical energy storage module may for example comprise a capacitor (or several interconnected capacitors). The value of the capacitance of the second electrical energy storage module may at least in part govern the rise time and possibly amplitude of any electrical pulse generated by the electrical pulse generating arrangement. Thus, by appropriate selection of the second electrical energy storage module (e.g., so that the second electrical energy storage module has a certain capacitance), the rise time and possibly amplitude of any electrical pulse generated by the electrical pulse generating arrangement may be tailored as required or desired by the application (e.g., by the type of load).

Each or any of the first electrical energy storage module and the second electrical energy storage module may comprise or be constituted by one or more capacitors. In alternative or in addition, each or any of the first electrical energy storage module and the second electrical energy storage module may comprise or be constituted by another or other types of electrical energy storage modules than capacitors, e.g., inductive electrical energy storage modules.

The power supply may for example comprise a power converter. For example, the power supply may comprise or be connectable to an Alternating Current (AC) source, and may further comprise a rectifier for converting AC from the AC source into Direct Current (DC) which can be used to charge the first electrical energy storage module.

In the context of the present application, by a non-conducting state of the switch unit it is meant a state where there is no or only very little conduction of current through the switch unit. Thus, the switch unit may be switchable so as to stop, or substantially stop, the switch unit from conducting current through the switch unit.

The load may for example comprise or be constituted by one or more of a microwave amplifier, a klystron, a magnetron, or a particle emitter, such as, for example, an electron emitter (which may be referred to as an electron gun).

The first resistor, the inductor and the second electrical energy storage may for example be connected in parallel.

The electrical pulse shape adjustment circuit may comprise a second resistor, which may be connected in series with the second electrical energy storage module. The series connection of the second resistor and the second electrical energy storage module, the first resistor and the inductor may be connected in parallel. Thus, the electrical pulse shape adjustment circuit may comprise (or possibly consist of) three components connected in parallel—(1) the series connection of the second resistor and the second electrical energy storage module, (2) the first resistor, and (3) the inductor.

The second resistor may be referred to as a series resistor. The second resistor may act as a current limiter, e.g., at the beginning of the electrical pulse(s), such as, for example, up to the first millisecond of the electrical pulse(s), so as to govern the distribution of the current between the first resistor and the second resistor. Arranging the second resistor in the electrical pulse shape adjustment circuit may thereby further facilitate ensuring that the first resistor of the electrical pulse shape adjustment circuit is not ‘active’ from the beginning of the electrical pulse. Further, by providing the second resistor with a selected resistance or a resistance within a selected resistance range, it may be further facilitated to ensure that the first resistor of the electrical pulse shape adjustment circuit is not ‘active’ during a selected first part of the duration of the electrical pulse(s) from the beginning of the electrical pulse(s). As mentioned in the foregoing, the second electrical energy storage module of the electrical pulse shape adjustment circuit may facilitate or allow for ensuring that the first resistor of the electrical pulse shape adjustment circuit is not ‘active’ from the beginning of the electrical pulse, due to the second electrical energy storage module of the electrical pulse shape adjustment circuit being charged at the beginning of the electrical pulse. The time it takes to charge the second electrical energy storage module of the electrical pulse shape adjustment circuit at the beginning of the electrical pulse may be referred to as the time the second electrical energy storage module is ‘active’ at the beginning of the electrical pulse. The time the second electrical energy storage module is ‘active’ at the beginning of the electrical pulse may depend on the resistance of the second resistor. Thus, by providing the second resistor with a selected resistance or a resistance within a selected resistance range, it may be tailored to what degree the first resistor of the electrical pulse shape adjustment circuit is ‘active’ during a selected first part of the duration of the electrical pulse(s) from the beginning of the electrical pulse(s), or how long the first resistor of the electrical pulse shape adjustment circuit is not ‘active’ at the beginning of the electrical pulse. As mentioned in the foregoing, the second electrical energy storage module may for example comprise a capacitor (or several interconnected capacitors). The value of the capacitance of the second electrical energy storage module and the resistance of the resistor may govern the rise time and possibly amplitude of any electrical pulse generated by the electrical pulse generating arrangement. Thus, by appropriate selection of the second electrical energy storage module and the second resistor (e.g., so that the second electrical energy storage module has a certain capacitance, and so that the second resistor has a certain resistance), the rise time and possibly amplitude of any electrical pulse generated by the electrical pulse generating arrangement may be tailored as required or desired by the application (e.g., by the type of load).

The electrical pulse generating arrangement may comprise a transformer, which may be arranged (e.g., in relation to the load and the transformer) such that any electrical pulse generated by discharge of the first electrical energy storage module is conveyed to the load via the transformer.

The electrical pulse generating module may comprise a switch unit (or switch, or switch element) controllably switchable between at least a conducting state and a non-conducting state (or substantially non-conducting state). The switch unit may be connected to the power supply and to the first electrical energy storage module, respectively, such that the power supply charges the first electrical energy storage module by way of a charging current supplied by the power supply, or the first electrical energy storage module is discharged so as to create an electrical pulse to be conveyed to the load, based on switching of the at least one switch unit between at least the conducting state and the (substantially) non-conducting state thereof.

The switch unit may for example comprise one or more solid-state semiconductor switching devices with turn-on and turn-off capability, such as, for example, at least one Insulated-Gate Bipolar Transistor (IGBT), Integrated Gate-Commutated Transistor (IGCT), metal oxide semiconductor field effect transistor (MOSFET) and/or gate turn-off thyristor (GTO), but is not limited thereto.

The electrical pulse shape adjustment circuit may be connected between the switch unit and the transformer. For example, the electrical pulse shape adjustment circuit may be connected between the switch unit and a primary winding of the transformer. In the case the transformer is a step-up transformer, this may correspond to that the electrical pulse shape adjustment circuit is connected at the low voltage side of the transformer.

The electrical pulse generating arrangement may comprise a plurality of electrical pulse shape adjustment circuits. The transformer may have a plurality of primary windings. Each of the electrical pulse shape adjustment circuits may be connected between the switch unit and a corresponding one of the primary windings. Only one electrical pulse shape adjustment circuit may be connected to each primary winding. Thus, each electrical pulse shape adjustment circuit may be connected to a corresponding primary winding of the transformer.

The electrical pulse shape adjustment circuit may be connected between the transformer and the load. For example, the electrical pulse shape adjustment circuit may be connected between a secondary winding of the transformer and the load. In the case the transformer is a step-up transformer, this may correspond to that the electrical pulse shape adjustment circuit is connected at the high voltage side of the transformer.

The electrical pulse generating arrangement may comprise a plurality of electrical pulse shape adjustment circuits. The transformer may have a plurality of secondary windings. Each of the electrical pulse shape adjustment circuits may be connected between the load and a corresponding one of the secondary windings. Only one electrical pulse shape adjustment circuit may be connected to each secondary winding. Thus, each electrical pulse shape adjustment circuit may be connected to a corresponding secondary winding of the transformer.

The electrical pulse generating arrangement may comprise a plurality of electrical pulse shape adjustment circuits. The plurality of electrical pulse shape adjustment circuits may include at least a first electrical pulse shape adjustment circuit and a second electrical pulse shape adjustment circuit. The first electrical pulse shape adjustment circuit may be connected between the switch unit and the transformer. The second electrical pulse shape adjustment circuit may be connected between the transformer and the load. The first electrical pulse shape adjustment circuit may for example be connected between the switch unit and a primary winding of the transformer. The second electrical pulse shape adjustment circuit may for example be connected between a secondary winding of the transformer and the load.

A resistance of the first resistor and an inductance of the inductor may be selected such that an RL time constant of the first resistor and the inductor corresponds to a desired pulse duration of any electrical pulse generated by the electrical pulse generating arrangement. If the resistance of the first resistor is R₁ and the inductance of the inductor is L, the RL time constant of the first resistor and the inductor may be given by L/R₁.

A resistance of the first resistor may for example be in a range 1 mΩ to 200 mΩ.

An inductance of the inductor may for example be in a range 0.1 μH to 100 μH.

As mentioned in the foregoing, the second electrical energy storage module may for example comprise a capacitor (or several interconnected capacitors). A value of the capacitance of the second electrical energy storage module and a value of the resistance of the second resistor may for example be selected so as to achieve a certain rise time and possibly amplitude of any electrical pulse generated by the electrical pulse generating arrangement, as described in the foregoing.

A resistance of the second resistor may for example be in a range 1 mΩ to 100 mΩ.

A capacitance of the second electrical energy storage module may for example be in a range 1 μF to 200 μF.

The electrical pulse generating arrangement may for example be configured such that the pulse duration of any electrical pulse generated by the electrical pulse generating arrangement is in a range from just above 0 s to (about) 25 μs, e.g., from (about) 0.5 μs to (about) 25 μs.

According to a second aspect a system is provided. The system comprises a load and an electrical pulse generating arrangement according to the first aspect, which electrical pulse generating arrangement is connected to the load.

Further objects and advantages of the present invention are described in the following by means of exemplifying embodiments. It is noted that the present invention relates to all possible combinations of features recited in the claims. Further features of, and advantages with, the present invention will become apparent when studying the appended claims and the description herein. Those skilled in the art realize that different features of the present invention can be combined to create embodiments other than those described herein.

### BRIEF DESCRIPTION OF THE DRAWINGS

Exemplifying embodiments of the present invention will be described below with reference to the accompanying drawings.

FIGS. 1 and 2 are schematic circuit diagrams of an electrical pulse generating arrangement according to embodiments of the present invention.

All the figures are schematic, not necessarily to scale, and generally only show parts which are necessary in order to elucidate embodiments of the present invention, wherein other parts may be omitted or merely suggested.

### DETAILED DESCRIPTION

The present invention will now be described hereinafter with reference to the accompanying drawings, in which exemplifying embodiments of the present invention are shown. The present invention may, however, be embodied in many different forms and should not be construed as limited to the embodiments of the present invention set forth herein; rather, these embodiments are provided by way of example so that this disclosure will convey the scope of the present invention to those skilled in the art.

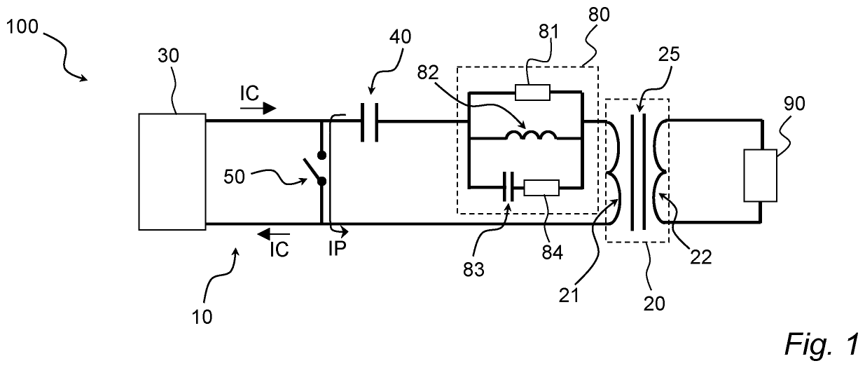

FIG. 1 is a schematic circuit diagram of an electrical pulse generating arrangement 100 according to an embodiment of the present invention. The electrical pulse generating arrangement 100 is connected to a load 90. The load 90 may for example comprise or be constituted by one or more of a microwave amplifier, a klystron, a magnetron, or a particle emitter.

The electrical pulse generating arrangement 100 comprises an electrical pulse generating module 10. The electrical pulse generating module 10 comprises a first electrical energy storage module 40 and a power supply 30. The power supply 30 is configured to selectively charge the first electrical energy storage module 40.

In accordance with the embodiment of the present invention illustrated in FIG. 1, the first electrical energy storage module 40 comprises a capacitor. It is however to be understood that the first electrical energy storage module 40 could comprise several capacitors (e.g., a capacitor bank) and/or another or other types of electrical energy storage modules than capacitors, e.g., inductive electrical energy storage modules.

The power supply 30 may for example comprise a power converter. For example, the power supply may comprise or be connectable to an Alternating Current (AC) source (not shown in FIG. 1), and may further comprise a rectifier (not shown in FIG. 1) for converting AC from the AC source into Direct Current (DC) which can be used to charge the first electrical energy storage module 40. For example, the power supply 30 may be connectable or connected to a power source (not shown in FIG. 1) that is supplying AC power, having one phase or a plurality of phases. The power source could for example be configured to supply three-phase AC power. The power source could for example comprise or be constituted by an electrical grid, which may supply three-phase AC power, e.g., mains electric power. The power supply 30 could comprise an input rectifier (not shown in FIG. 1). The input rectifier may be is arranged to receive the AC power supplied by the power source when the power supply 30 is connected to the power source. The input rectifier may for example comprise or be constituted by a multi-phase rectifier, which may comprise a plurality of phase legs.

The electrical pulse generating module 10 is configured to generate one or more electrical pulses by charging and discharging of the first electrical energy storage module 40. When the first electrical energy storage module 40 is discharged, an electrical pulse is created to be conveyed to the load 90.

The electrical pulse generating arrangement 100 comprises an electrical pulse shape adjustment circuit 80, which in accordance with the embodiment of the present invention illustrated in FIG. 1 is connected in series with the load 90. The electrical pulse shape adjustment circuit 80 comprises a first resistor 81, an inductor 82 and a second electrical energy storage module 83.

The first resistor 81, the inductor 82 and the second electrical energy storage module 83 are interconnected. For example, and as illustrated in FIG. 1, the first resistor 81, the inductor 82 and the second electrical energy storage module 83 may be connected in parallel.

In accordance with the embodiment of the present invention illustrated in FIG. 1, the electrical pulse shape adjustment circuit 80 comprises a second resistor 84 connected in series with the second electrical energy storage module 83. It is to be understood that the second resistor 84 is optional and may be omitted. As illustrated in FIG. 1, the series connection of the second resistor 84 and the second electrical energy storage module 83, the first resistor 81 and the inductor 82 may be connected in parallel. Thus, the electrical pulse shape adjustment circuit 80 may comprise three components connected in parallel—(1) the series connection of the second resistor 84 and the second electrical energy storage module 83, (2) the first resistor 81, and (3) the inductor 82.

In accordance with the embodiment of the present invention illustrated in FIG. 1, the second electrical energy storage module 83 comprises a capacitor. It is however to be understood that the second electrical energy storage module 83 could comprise several capacitors (e.g., a capacitor bank) and/or another or other types of electrical energy storage modules than capacitors, e.g., inductive electrical energy storage modules.

In accordance with the embodiment of the present invention illustrated in FIG. 1, the electrical pulse generating arrangement comprises a transformer 20. As illustrated in FIG. 1, the transformer 20 is arranged such that any electrical pulse generated by discharge of the first electrical energy storage module 40 is conveyed to the load 90 via the transformer 20. The transformer 20 may comprise at least one core 25.

Further in accordance with the embodiment of the present invention illustrated in FIG. 1, the electrical pulse generating module 10 comprises a switch unit 50. The switch unit 50 is controllably switchable between at least a conducting state and a non-conducting state (or substantially non-conducting state). The switch unit 50 is connected to the power supply 30 and to the first electrical energy storage module 40, respectively, such that the power supply 30 charges the first electrical energy storage module 40 by way of a charging current supplied by the power supply 30, or the first electrical energy storage module 40 is discharged so as to create an electrical pulse to be conveyed to the load 90, based on switching of the at least one switch unit 50 between at least the conducting state and the non-conducting state (or substantially non-conducting state) thereof.

The switch unit 50 could for example comprise one or more solid-state semiconductor switching devices, such as, for example, at least one IGBT, IGCT, MOSFET and/or GTO, and/or another or other types of electronic switching devices with turn-on and turn-off capability.

As illustrated in FIG. 1, the electrical pulse shape adjustment circuit 80 is connected between the switch unit 50 and the transformer 20.

The transformer 20 may comprise at least one primary winding 21 by which the transformer 20 may be connected to the electrical pulse generating module 10. For example, the transformer 20 may be connected to the electrical pulse generating module 10 by way of two terminals thereof, as illustrated in FIG. 1. In accordance with the embodiment of the present invention illustrated in FIG. 1 and as indicated therein, the transformer 20 may comprise two primary windings 21 by which the transformer 20 may be connected to the electrical pulse generating module 10. However, it is to be understood that the number of primary windings of the transformer 20 by which the transformer 20 may be connected to the electrical pulse generating module 10 is not limited to two, but may for example be larger than two. The primary winding(s) of the transformer 20 may be configured to receive the electrical pulse(s) generated by the electrical pulse generating module 10.

As illustrated in FIG. 1, the electrical pulse shape adjustment circuit 80 is connected between the switch unit 50 and the primary windings 21 of the transformer 20.

It is to be understood that the electrical pulse generating arrangement 100 could possibly comprise a plurality of electrical pulse shape adjustment circuits, and not only one electrical pulse shape adjustment circuit 80 as illustrated in FIG. 1. The transformer 20 could have a plurality of primary windings, and each of the electrical pulse shape adjustment circuits may be connected between the switch unit 50 and a corresponding one of the primary windings of the transformer 20, wherein only one electrical pulse shape adjustment circuit may be connected to each primary winding.

In accordance with the embodiment of the present invention illustrated in FIG. 1, the charging current that is supplied by the power supply 30 when the switch unit 50 is switched into the non-conducting state may flow out of the power supply 30 via the conductor of the two conductors connected to the power supply 30 that is uppermost in FIG. 1, and return to the power supply 30 via the conductor of the two conductors connected to the power supply 30 that is lowermost in FIG. 1, as indicated by the arrows IC in FIG. 1. The two above-mentioned conductors may for example be connected to two terminals of the power supply 30.

Further in accordance with the embodiment of the present invention illustrated in FIG. 1, the current of an electrical pulse, which is generated when the electrical energy storage module 40 is discharged, may for example flow in the direction indicated by the arrow IP in FIG. 1. The electrical pulse generating arrangement 100 may for example be configured such that the duration of each or any electrical pulse that is generated is in a range from 0.5 μs to 25 μs, for example.

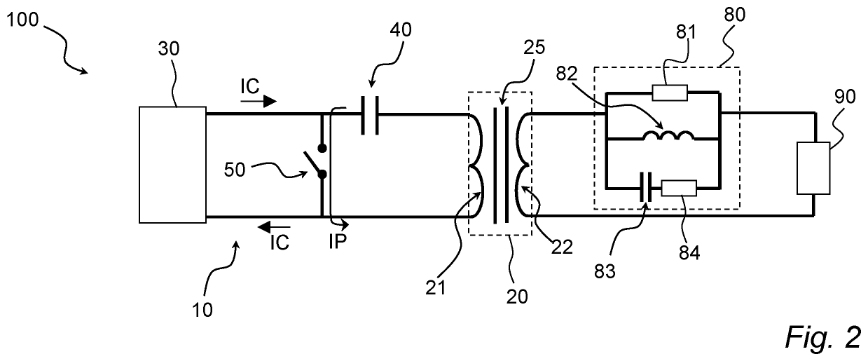

FIG. 2 is a schematic circuit diagram of an electrical pulse generating arrangement 100 according to an embodiment of the present invention. The electrical pulse generating arrangement 100 illustrated in FIG. 2 is similar to the electrical pulse generating arrangement 100 illustrated in FIG. 1, and the same reference numerals in FIGS. 1 and 2 denote the same or similar components, having the same or similar function.

In contrast to the electrical pulse generating arrangement 100 illustrated in FIG. 1, in the electrical pulse generating arrangement 100 illustrated in FIG. 2, the electrical pulse shape adjustment circuit 80 is not connected between the switch unit 50 and the primary windings 21 of the transformer 20, but is instead connected between the transformer 20 and the load 90. As illustrated in FIG. 2, the electrical pulse shape adjustment circuit 80 may be connected between secondary windings 22 of the transformer 20 and the load 90.

In conclusion, an electrical pulse generating arrangement is disclosed. The electrical pulse generating arrangement is connected or connectable to a load. The electrical pulse generating arrangement comprises an electrical pulse generating module, which comprises a first electrical energy storage module and a power supply configured to selectively charge the first electrical energy storage module. The electrical pulse generating module is configured to generate one or more electrical pulses by charging and discharging of the first electrical energy storage module, wherein when the first electrical energy storage module is discharged, an electrical pulse is created to be conveyed to the load. The electrical pulse generating arrangement comprises an electrical pulse shape adjustment circuit connected or connectable in series with the load. The electrical pulse shape adjustment circuit comprises at least a first resistor, an inductor and a second electrical energy storage module.

While the present invention has been illustrated in the appended drawings and the foregoing description, such illustration is to be considered illustrative or exemplifying and not restrictive; the present invention is not limited to the disclosed embodiments. Other variations to the disclosed embodiments can be understood and effected by those skilled in the art in practicing the claimed invention, from a study of the drawings, the disclosure, and the appended claims. In the appended claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting the scope.

1-14. (canceled)

15. An electrical pulse generating arrangement connected or connectable to a load, the electrical pulse generating arrangement comprising:
an electrical pulse generating module comprising:
a first electrical energy storage module; and
a power supply configured to selectively charge the first electrical energy storage module;
wherein the electrical pulse generating module is configured to generate one or more electrical pulses by charging and discharging of the first electrical energy storage module, wherein when the first electrical energy storage module is discharged, an electrical pulse is created to be conveyed to the load; and
an electrical pulse shape adjustment circuit connected or connectable in series with the load, the electrical pulse shape adjustment circuit comprising at least a first resistor, an inductor and a second electrical energy storage module, the first resistor, the inductor and the second electrical energy storage module being interconnected, wherein the first resistor, the inductor and the second electrical energy storage are connected in parallel.

16. An electrical pulse generating arrangement according to claim 15, wherein the electrical pulse shape adjustment circuit further comprises a second resistor connected in series with the second electrical energy storage module, wherein the series connection of the second resistor and the second electrical energy storage module, the first resistor, the inductor and the second electrical energy storage are connected in parallel.

17. An electrical pulse generating arrangement according to claim 1, further comprising a transformer, the transformer being arranged such that any electrical pulse generated by discharge of the first electrical energy storage module is conveyed to the load via the transformer;
wherein the electrical pulse generating module comprises a switch unit controllably switchable between at least a conducting state and a non-conducting state, wherein the switch unit is connected to the power supply and to the first electrical energy storage module, respectively, such that the power supply charges the first electrical energy storage module by way of a charging current supplied by the power supply, or the first electrical energy storage module is discharged so as to create an electrical pulse to be conveyed to the load, based on switching of the at least one switch unit between at least the conducting state and the non-conducting state thereof.

18. An electrical pulse generating arrangement according to claim 17, wherein the electrical pulse shape adjustment circuit is connected between the switch unit and the transformer.

19. An electrical pulse generating arrangement according to claim 17, comprising a plurality of electrical pulse shape adjustment circuits, wherein the transformer has a plurality of primary windings, and wherein each of the electrical pulse shape adjustment circuits is connected between the switch unit and a corresponding one of the primary windings, wherein only one electrical pulse shape adjustment circuit is connected to each primary winding.

20. An electrical pulse generating arrangement according to claim 17, wherein the electrical pulse shape adjustment circuit is connected between the transformer and the load.

21. An electrical pulse generating arrangement according to claim 17, comprising a plurality of electrical pulse shape adjustment circuits, wherein the transformer has a plurality of secondary windings, and wherein each of the electrical pulse shape adjustment circuits is connected between the load and a corresponding one of the secondary windings, wherein only one electrical pulse shape adjustment circuit is connected to each secondary winding.

22. An electrical pulse generating arrangement according to claim 3, comprising a plurality of electrical pulse shape adjustment circuits including at least a first electrical pulse shape adjustment circuit and a second electrical pulse shape adjustment circuit, wherein the first electrical pulse shape adjustment circuit is connected between the switch unit and the transformer and the second electrical pulse shape adjustment circuit is connected between the transformer and the load.

23. An electrical pulse generating arrangement according to claim 15, wherein a resistance of the first resistor and an inductance of the inductor are selected such that an RL time constant of the first resistor and the inductor corresponds to a desired pulse duration of any electrical pulse generated by the electrical pulse generating arrangement.

24. An electrical pulse generating arrangement according to claim 15, wherein the second electrical energy storage module comprises a capacitor, and wherein a capacitance of the second electrical energy storage module is in a range 1 μF to 200 μF.

25. An electrical pulse generating arrangement according to claim 15, wherein a resistance of the first resistor is in a range 1 mΩ to 200 mΩ, and an inductance of the inductor is in a range 0.1 μH to 100 μH.

26. An electrical pulse generating arrangement according to claim 16, wherein a resistance of the second resistor is in a range 1 mΩ to 100 mΩ.

27. An electrical pulse generating arrangement according to claim 15, wherein the electrical pulse generating arrangement is configured such that the pulse duration of any electrical pulse generated by the electrical pulse generating arrangement is in a range from 0.5 μs to 25 μs.

28. A system comprising a load and an electrical pulse generating arrangement according to claim 1 connected to the load.
